(19) United States
(12) Patent Application Publication
(10) Pub. No.: US 2026/0352172 A1
(43) Pub. Date: Nov. 5, 2026

(54) Ping-pong amplifier with auto-zeroing

(71) Applicant: NOVATEK Microelectronics Corp., Hsin-Chu (TW)

(72) Inventors: En-Li Chen, Hsinchu City (TW); Kuo-Che Hong, Hsinchu City (TW); Chih-Cheng Chen, Yunlin County (TW); Hung-Po Kuo, Tainan City (TW)

(73) Assignee: NOVATEK Microelectronics Corp., Hsin-Chu (TW)

(21) Appl. No.: 19/198,136

(22) Filed: May 5, 2025

(51) Int. Cl. H03F 3/45

(52) U.S. Cl. CPC H03F 3/45977; H03F 3/45475; H03F 2200/375

(57) ABSTRACT

A ping-pong amplifier includes a ping stage and a pong stage. The ping stage includes a first input stage, a first gain stage, a first output stage and a first storage capacitor. The first input stage includes a first buffer circuit and a first auto-zeroing circuit. The first storage capacitor is coupled to the first auto-zeroing circuit. The pong stage, coupled to the ping stage, includes a second input stage, a second gain stage, a second output stage and a second storage capacitor. The second input stage includes a second buffer circuit and a second auto-zeroing circuit. The second storage capacitor is coupled to the second auto-zeroing circuit. The first output stage is coupled to the first gain stage or the second gain stage, and the second output stage is coupled to the first gain stage or the second gain stage.

### BACKGROUND OF THE INVENTION

### 1. Field of the Invention

The present invention relates to a ping-pong amplifier, and more particularly, to a ping-pong amplifier capable of auto-zeroing function for offset cancellation.

### 2. Description of the Prior Art

An auto-zeroing amplifier has the advantages of low output offset and low output ripple. The offset refers to the errors and/or mismatches of differential pairs in the amplifier. In order to achieve a satisfactory accuracy of output signals, the output offset is required to be as small as possible. The output ripple refers to the ripple on the output signals, and is also required to be as small as possible. In general, the low output offset of the auto-zeroing amplifier is achieved by sampling the offset value of the amplifier in a sampling phase and then generating the output signal with the automatically canceled offset value in a driving phase. Therefore, the auto-zeroing amplifier may have a discrete-time output feature since the output voltage is provided only in the driving phase.

In order to improve this problem, a ping-pong architecture is applied to be integrated with the auto-zeroing amplifier, to realize a ping-pong amplifier. The ping-pong amplifier includes two circuit stages which may provide output voltages alternately to generate a continuous-time output.

The conventional ping-pong amplifier requires that the feedback circuit for offset sampling is connected in front of the output stage, and thus an additional V-to-I conversion circuit is necessary to generate a feedback current, and the V-to-I conversion circuit requires additional circuit cost. In addition, in the conventional ping-pong amplifier, the ping stage and the pong stage perform ping-pong operations by sharing the same output stage. If the ping-pong amplifier applies the structure of a class-AB amplifier, each of the ping stage and the pong stage needs two capacitors for storing the offset value, resulting in a larger circuit area and also a higher circuit cost.

### SUMMARY OF THE INVENTION

It is therefore an objective of the present invention to provide a novel circuit structure of the ping-pong amplifier, in order to solve the abovementioned problems.

An embodiment of the present invention discloses a ping-pong amplifier, which comprises a ping stage and a pong stage. The ping stage comprises a first input stage, a first gain stage, a first output stage and a first storage capacitor. The first input stage comprises a first buffer circuit and a first auto-zeroing circuit. The first gain stage is coupled to the first input stage. The first storage capacitor is coupled to the first auto-zeroing circuit. The pong stage, coupled to the ping stage, comprises a second input stage, a second gain stage, a second output stage and a second storage capacitor. The second input stage comprises a second buffer circuit and a second auto-zeroing circuit. The second gain stage is coupled to the second input stage. The second storage capacitor is coupled to the second auto-zeroing circuit. The first output stage is coupled to the first gain stage or the second gain stage, and the second output stage is coupled to the first gain stage or the second gain stage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a ping-pong amplifier according to an embodiment of the present invention.

FIG. 2A and FIG. 2B illustrate the operations of the ping-pong amplifier shown in FIG. 1.

FIG. 3 is a waveform diagram of the control signals of the ping-pong amplifier.

FIG. 4A and FIG. 4B are schematic diagrams of an exemplary implementation of the ping-pong amplifier according to an embodiment of the present invention.

FIG. 5 is a schematic diagram of a display system according to an embodiment of the present invention.

### DETAILED DESCRIPTION

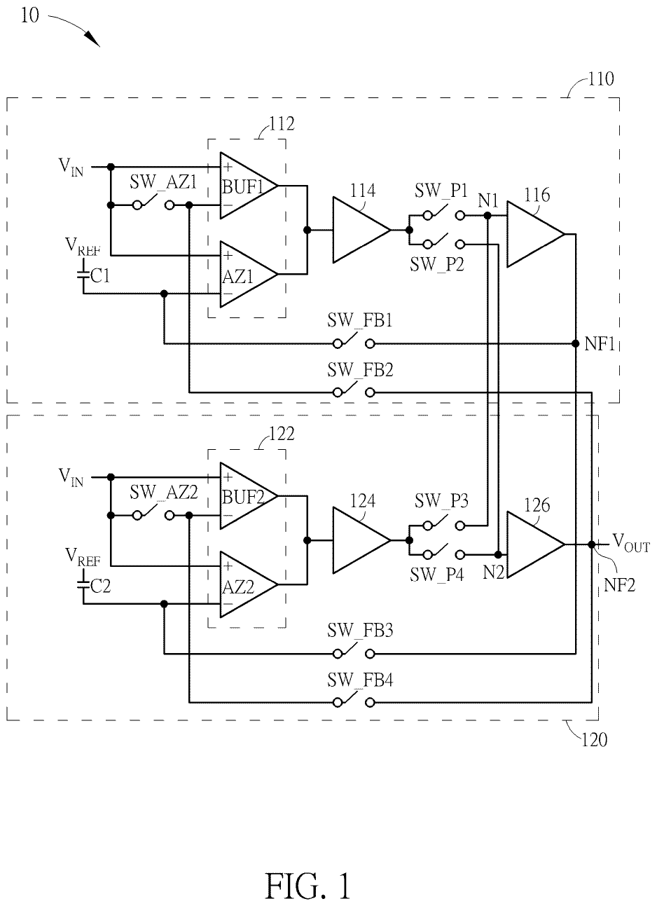

FIG. 1 is a schematic diagram of a ping-pong amplifier 10 according to an embodiment of the present invention. The ping-pong amplifier 10 is configured to generate and output an output signal V_{OUT} by receiving an input signal V_{IN}. In detail, the ping-pong amplifier 10 includes a ping stage 110 and a pong stage 120. The ping stage 110 and the pong stage 120 may have a similar structure, to perform auto-zeroing and output driving alternately.

As shown in FIG. 1, the ping stage 110 includes an input stage 112, a gain stage 114 and an output stage 116, and the pong stage 120 includes an input stage 122, a gain stage 124 and an output stage 126. In the ping stage 110, the input terminal of the gain stage 114 is coupled to the output terminal of the input stage 112, and the input terminal of the output stage 116 (i.e., the node N1) may be coupled to the output terminal of the gain stage 114 and/or the output terminal of the gain stage 124. Similarly, in the pong stage 120, the input terminal of the gain stage 124 is coupled to the output terminal of the input stage 122, and the input terminal of the output stage 126 (i.e., the node N2) may be coupled to the output terminal of the gain stage 114 and/or the output terminal of the gain stage 124.

In the ping stage 110, the input stage 112 includes a buffer circuit BUF1 and an auto-zeroing circuit AZ1. The buffer circuit BUF1 is coupled between the input terminal of the ping-pong amplifier 10 and the gain stage 114. More specifically, the buffer circuit BUF1 includes a positive input terminal, a negative input terminal and an output terminal. The positive input terminal of the buffer circuit BUF1 is coupled to the input terminal of the ping-pong amplifier 10, to receive the input signal V_{IN}. The output terminal of the buffer circuit BUF1 is coupled to the input terminal of the gain stage 114. The buffer circuit BUF1 may be operated as a buffer to generate a current to be output to the gain stage 114 by receiving the input signal V_{IN}. The auto-zeroing circuit AZ1 is coupled between the input terminal of the ping-pong amplifier 10 and the gain stage 114. More specifically, the auto-zeroing circuit AZ1 also includes a positive input terminal, a negative input terminal and an output terminal. The positive input terminal of the auto-zeroing circuit AZ1 is coupled to the input terminal of the ping-pong amplifier 10, to receive the input signal V_{IN}. The output terminal of the auto-zeroing circuit AZ1 is coupled to the input terminal of the gain stage 114. The negative input terminal of the auto-zeroing circuit AZ1 is further coupled to a storage capacitor C1. In addition, a sampling switch SW_AZ1 is coupled between the positive input terminal and the negative input terminal of the buffer circuit BUF1, to sample the offset value of the input stage 112 and the gain stage 114 when conducted. The sampled offset value is then sent to the storage capacitor C1 through the feedback structure of the ping stage 110, to be stored in the storage capacitor C1.

The storage capacitor C1 may be coupled between the negative input terminal of the auto-zeroing circuit AZ1 and a reference node for receiving a reference voltage V_{REF}. In one or some embodiments, the reference node may be a ground terminal, and thus the reference voltage V_{REF} is a ground voltage. In one or some embodiments, the reference node may be the input terminal of the ping-pong amplifier 10, and thus the reference voltage V_{REF} is equal to the voltage of the input signal V_{IN}. Note that the input terminal of the ping-pong amplifier 10 may come from a node of a resistor string, which is usually less noisy than the ground terminal. In such a situation, it is preferable to couple the storage capacitor C1 to a noise-free node such as the input terminal of the ping-pong amplifier 10, in order to minimize the noise interferences on the offset value stored in the storage capacitor C1.

The gain stage 114 may receive the current from the input stage 112 to generate a driving current, and provide the driving current for the output stage 116 (and/or for the output stage 126). The output stage 116 thereby generates the output signal V_{OUT} according to the driving current. In one or some embodiments, the implementations of the gain stage 114 and the output stage 116 may have the structure of a class-AB amplifier.

The structure of the pong stage 120 is similar to the structure of the ping stage 110. In the pong stage 120, the input stage 122 also includes a buffer circuit BUF2 and an auto-zeroing circuit AZ2. The buffer circuit BUF2 is coupled to another sampling switch SW_AZ2 for sampling the offset value, and the auto-zeroing circuit AZ2 is coupled to another storage capacitor C2 for storing the offset value. The detailed operations of the input stage 122, the gain stage 124, the output stage 126, the storage capacitor C2 and the sampling switch SW_AZ2 are similar to those of the input stage 112, the gain stage 114, the output stage 116, the storage capacitor C1 and the sampling switch SW_AZ1, and will not be narrated herein.

In order to realize the ping-pong operations, a set of ping-pong switches may be coupled between the gain stages 114 and 124 and the output stages 116 and 126. As shown in FIG. 1, there are four ping-pong switches SW_P1-SW_P4 implemented in the ping-pong amplifier 10. The ping-pong switch SW_P1 is coupled between the gain stage 114 and the input terminal of the output stage 116 (i.e., the node N1). The ping-pong switch SW_P2 is coupled between the gain stage 114 and the input terminal of the output stage 126 (i.e., the node N2). The ping-pong switch SW_P3 is coupled between the gain stage 124 and the input terminal of the output stage 116 (i.e., the node N1). The ping-pong switch SW_P4 is coupled between the gain stage 124 and the input terminal of the output stage 126 (i.e., the node N2). In this embodiment, the ping-pong switches SW_P1-SW_P4 are coupled in front of the output stages 116 and 126. In such a situation, the output signal V_{OUT} will not be directly affected by the switching of the ping-pong switches SW_P1-SW_P4, thereby reducing the ripples on the output signal V_{OUT}.

In addition, a set of feedback switches may be coupled between the input stages 112 and 122 and the output stages 116 and 126. As shown in FIG. 1, there are four feedback switches SW_FB1-SW_FB4 implemented in the ping-pong amplifier 10. The feedback switch SW_FB1 is coupled between the negative input terminal of the auto-zeroing circuit AZ1 and the output terminal of the output stage 116 (i.e., the feedback node NF1). The feedback switch SW_FB2 is coupled between the negative input terminal of the buffer circuit BUF1 and the output terminal of the output stage 126 (i.e., the feedback node NF2). The feedback switch SW_FB3 is coupled between the negative input terminal of the auto-zeroing circuit AZ2 and the output terminal of the output stage 116 (i.e., the feedback node NF1). The feedback switch SW_FB4 is coupled between the negative input terminal of the buffer circuit BUF2 and the output terminal of the output stage 126 (i.e., the feedback node NF2).

Note that FIG. 1 shows that the ping-pong switches SW_P1 and SW_P2 and the feedback switches SW_FB1 and SW_FB2 are included in the ping stage 110 and that the ping-pong switches SW_P3 and SW_P4 and the feedback switches SW_FB3 and SW_FB4 are included in the pong stage 120, but it is not necessary to implement in this way. Since the set of ping-pong switches SW_P1-SW_P4 and the set of feedback switches SW_FB1-SW_FB4 are cross-coupled between the circuit blocks of the ping stage 110 and the pong stage 120, each of the ping-pong switches SW_P1-SW_P4 and each of the feedback switches SW_FB1-SW_FB4 may be considered as being included in the ping stage 110 or the pong stage 120, or may be considered as being independent to any of the ping stage 110 and the pong stage 120.

In order to realize the continuous-time output (i.e., to output the output signal V_{OUT} continuously), the input stage 112 and the gain stage 114 of the ping stage 110 are operated as a buffer to output the output signal V_{OUT} when the input stage 122 and the gain stage 124 of the pong stage 120 are used to sample the offset value, and the input stage 122 and the gain stage 124 of the pong stage 120 are operated as a buffer to output the output signal V_{OUT} when the input stage 112 and the gain stage 114 of the ping stage 110 are used to sample the offset value. Note that the output terminal of the output stage 126 is the output terminal of the ping-pong amplifier 10 for outputting the output signal V_{OUT}, as shown in FIG. 1.

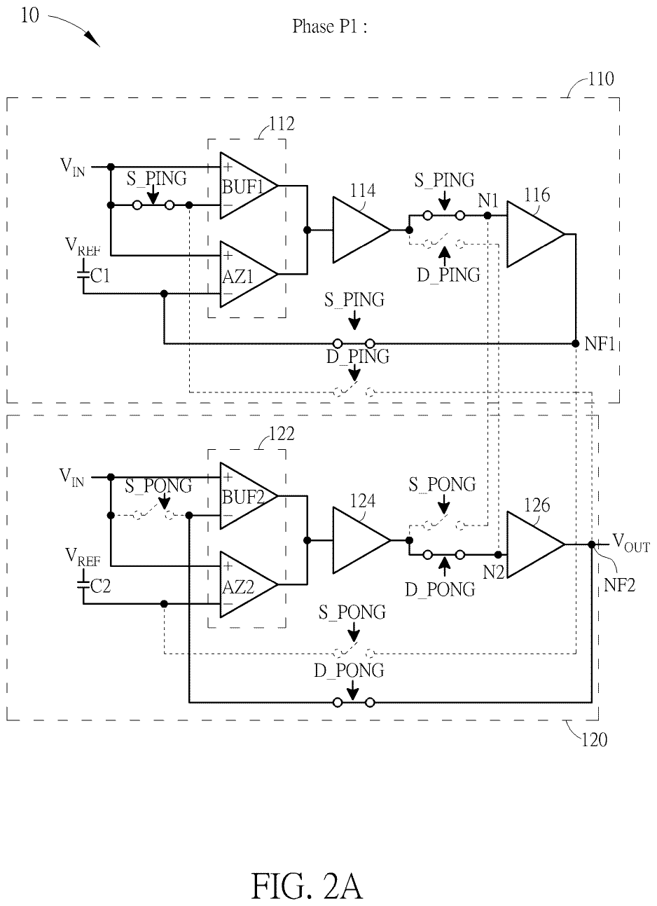

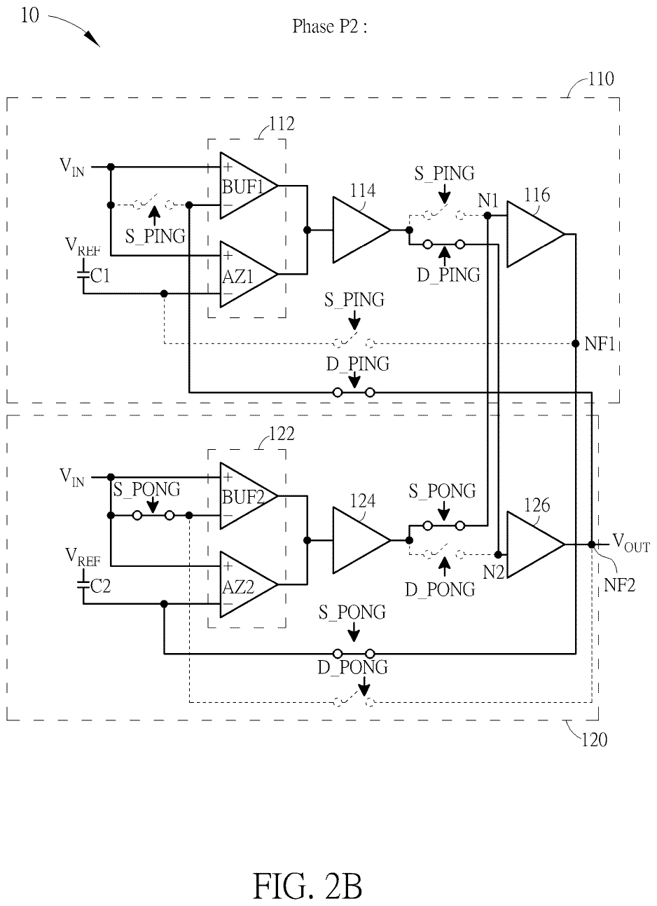

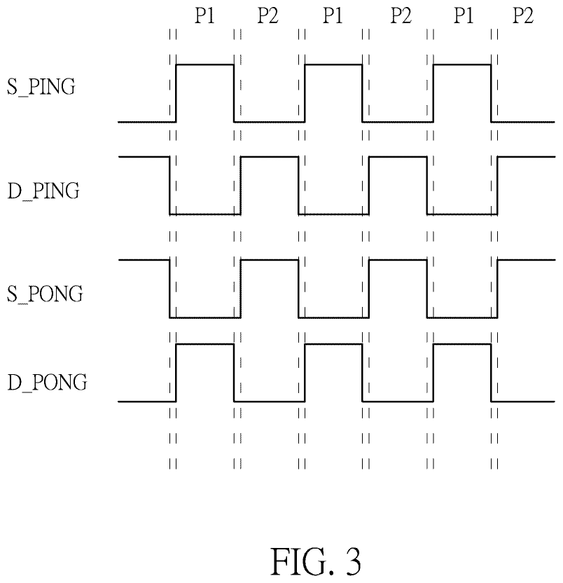

FIGS. 2A and 2B illustrate the operations of the ping-pong amplifier 10, where the switches in the ping-pong amplifier 10 are turned on or off in an appropriate manner to realize the auto-zeroing and ping-pong operations. Referring to FIGS. 2A and 2B along with FIG. 1, the sampling switch SW_AZ1, the ping-pong switch SW_P1 and the feedback switch SW_FB1 are controlled by a control signal S_PING, the ping-pong switch SW_P2 and the feedback switch SW_FB2 are controlled by a control signal D_PING, the sampling switch SW_AZ2, the ping-pong switch SW_P3 and the feedback switch SW_FB3 are controlled by a control signal S_PONG, and the ping-pong switch SW_P4 and the feedback switch SW_FB4 are controlled by a control signal D_PONG. The waveforms of the control signals S_PING, D_PING, S_PONG and D_PONG are shown in FIG. 3. In this embodiment, it is assumed that the control signals S_PING, D_PING, S_PONG and D_PONG in “High” level will turn on the corresponding switches, and in “Low” level will turn off the corresponding switches.

As shown in FIG. 3, each of the control signals S_PING, D_PING, S_PONG and D_PONG is pulled high with a time delay after other control signals are pulled low. This avoids an overlap between the conducting periods of different switches, so as to avoid leakage currents and/or other unwanted side effects. In another embodiment, the switching control between the phases P1 and P2 may be delayed in another manner or may be performed without delay, and the related operations and alterations do not serve to limit the scope of the present invention.

In addition, it can be seen in FIG. 3 that the control signals S_PING and D_PONG have the same waveform and may be the same signal, which means that the ping stage 110 performs auto-zeroing to sample the corresponding offset value when the pong stage 120 performs driving to output the output signal V_{OUT}. The control signals D_PING and S_PONG have the same waveform and may be the same signal, which means that the pong stage 120 performs auto-zeroing to sample the corresponding offset value when the ping stage 110 performs driving to output the output signal V_{OUT}.

Referring to FIG. 2A along with FIG. 1, where FIG. 2A illustrates the operations of the ping-pong amplifier 10 in the first phase P1. In this phase P1, the sampling switch SW_AZ1, the ping-pong switches SW_P1 and SW_P4, and the feedback switches SW_FB1 and SW_FB4 are turned on, while the sampling switch SW_AZ2, the ping-pong switches SW_P2 and SW_P3, and the feedback switches SW_FB2 and SW_FB3 are turned off. In such a situation, the input terminal of the output stage 116 is coupled to the output terminal of the gain stage 114 through the ping-pong switch SW_P1, and the input terminal of the output stage 126 is coupled to the output terminal of the gain stage 124 through the ping-pong switch SW_P4. The output terminal of the output stage 116 is coupled to the auto-zeroing circuit AZ1 and the storage capacitor C1 of the ping stage 110 through the feedback switch SW_FB1, and the output terminal of the output stage 126 is coupled to the buffer circuit BUF2 of the pong stage 120 through the feedback switch SW_FB4.

Therefore, the auto-zeroing operation is performed in the ping stage 110, where the offset value of the input stage 112 and the gain stage 114 is obtained and sent to be stored in the storage capacitor C1 through the ping-pong switch SW_P1 and the feedback switch SW_FB1. At this time, the pong stage 120 performs driving, where the input signal V_{IN} is forwarded through a signal path including the input stage 122, the gain stage 124, the ping-pong switch SW_P4 and the output stage 126, to generate the output signal V_{OUT}. The offset information stored in the storage capacitor C2 in the previous phase P2 is incorporated in the output signal V_{OUT} to reduce or cancel the overall offset.

Referring to FIG. 2B along with FIG. 1, where FIG. 2B illustrates the operations of the ping-pong amplifier 10 in the second phase P2. In this phase P2, the sampling switch SW_AZ2, the ping-pong switches SW_P2 and SW_P3, and the feedback switches SW_FB2 and SW_FB3 are turned on, while the sampling switch SW_AZ1, the ping-pong switches SW_P1 and SW_P4, and the feedback switches SW_FB1 and SW_FB4 are turned off. In such a situation, the input terminal of the output stage 116 is coupled to the output terminal of the gain stage 124 through the ping-pong switch SW_P3, and the input terminal of the output stage 126 is coupled to the output terminal of the gain stage 114 through the ping-pong switch SW_P2. The output terminal of the output stage 116 is coupled to the auto-zeroing circuit AZ2 and the storage capacitor C2 of the pong stage 120 through the feedback switch SW_FB3, and the output terminal of the output stage 126 is coupled to the buffer circuit BUF1 of the ping stage 110 through the feedback switch SW_FB2.

Therefore, the auto-zeroing operation is performed in the pong stage 120, where the offset value of the input stage 122 and the gain stage 124 is obtained and sent to be stored in the storage capacitor C2 through the ping-pong switch SW_P3 and the feedback switch SW_FB3. At this time, the ping stage 110 performs driving, where the input signal V_{IN} is forwarded through a signal path including the input stage 112, the gain stage 114, the ping-pong switch SW_P2 and the output stage 126, to generate the output signal V_{OUT}. The offset information stored in the storage capacitor C1 in the previous phase P1 is incorporated in the output signal V_{OUT} to reduce or cancel the overall offset.

Therefore, the output stage 126 in the pong stage 120 is always operated as an output buffer for outputting the output signal V_{OUT} to drive the next stage, and it can be seen in FIGS. 2A and 2B that the signal path is always through the output stage 126. The output stage 116 in the ping stage 110, which is alternately coupled to the auto-zeroing circuits AZ1 and AZ2 and the corresponding storage capacitors C1 and C2, is always used for auto-zeroing, and it can be seen in FIGS. 2A and 2B that the feedback path for offset storing is always through the output stage 116.

Note that since the output stage 126 is always operated as the output buffer in both phases P1 and P2, the offset of the output stage 126 may not be sampled in the sampling phase and thus may not be canceled. However, the offset cancellation effect is still satisfactory since the offsets contributed from other circuit stages can be well canceled through the auto-zeroing operations.

In a conventional ping-pong amplifier, the feedback circuit is connected to the front-end auto-zeroing circuit from the input terminal of the output stage, and thus the ping stage and the pong stage share the same output stage. Since the feedback circuit is connected from a pair of current nodes in front of the output stage, each of the ping stage and the pong stage is requested to have two storage capacitors for a pair of feedback nodes. In addition, an additional V-to-I conversion circuit is necessary to generate feedback currents, and this is accompanied by a larger circuit cost. In comparison, in the ping-pong amplifier of the present invention, the feedback circuit (i.e., the feedback switches) is connected to the front-end auto-zeroing circuit from the output terminal of the output stage, which means that the output terminal of the output stage is operated as a feedback node (i.e., NF1 and NF2). In such a situation, each of the ping stage and the pong stage may include only one storage capacitor coupled to the output terminal through the feedback circuit, thereby reducing the circuit areas of the capacitor elements. In addition, the number of V-to-I conversion circuits required in the ping-pong amplifier of the present invention may also be reduced.

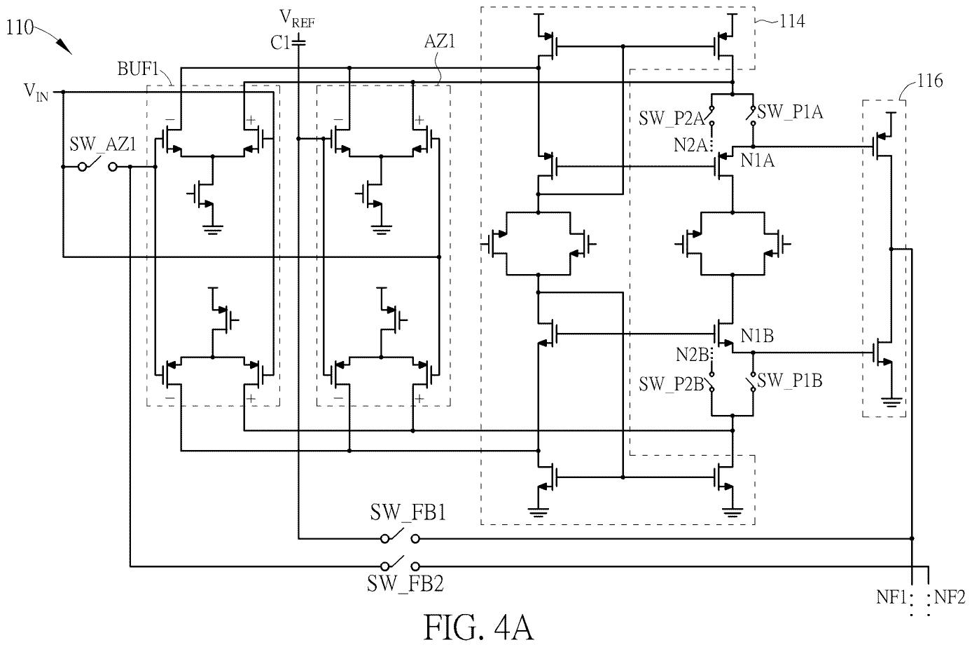

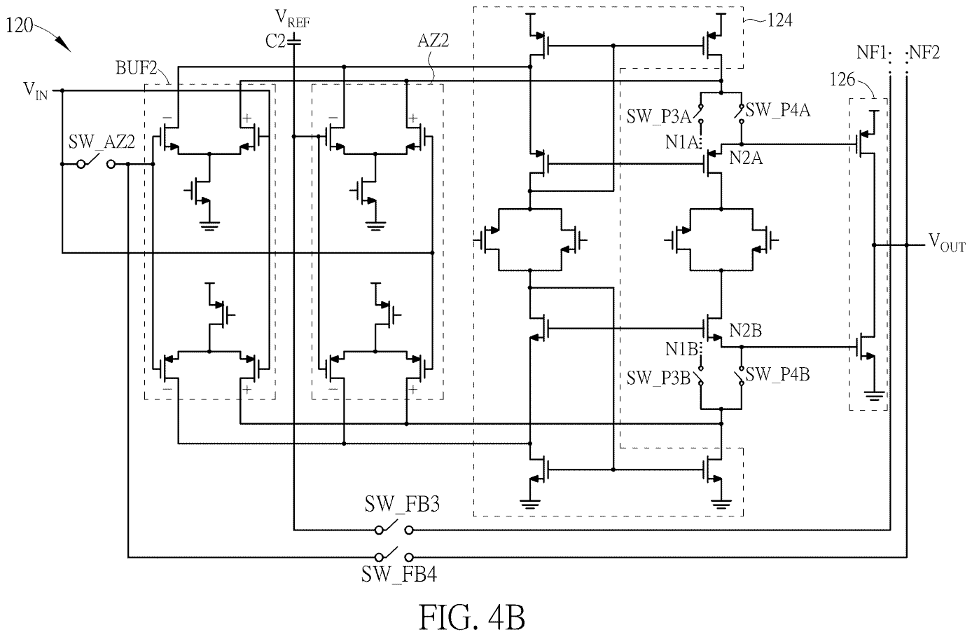

FIGS. 4A and 4B are schematic diagrams of an exemplary implementation of the ping-pong amplifier 10 according to an embodiment of the present invention, where a transistor-level structure is shown. FIG. 4A illustrates the detailed implementation of the ping stage 110, and FIG. 4B illustrates the detailed implementation of the pong stage 120. The circuit structure shown in FIG. 4A and the circuit structure shown in FIG. 4B may be combined to form the entire ping-pong amplifier 10. The circuit structures shown in FIGS. 4A and 4B are the circuit stages in a common class-AB amplifier, which are well known by a person of ordinary skill in the art and will not be detailed herein.

In this embodiment as shown in FIGS. 4A and 4B, the ping-pong switches are implemented in both the PMOS side and the NMOS side. Specifically, as shown in FIG. 4A, the ping stage 110 may include four ping-pong switches SW_P1A, SW_P1B, SW_P2A and SW_P2B. The ping-pong switches SW_P1A and SW_P1B, which are coupled between the output terminals of the gain stage 114 and the input terminals of the output stage 116 (i.e., the nodes N1A and N1B), are an implementation of the ping-pong switch SW_P1 shown in FIG. 1. The ping-pong switches SW_P2A and SW_P2B, which are coupled between the output terminals of the gain stage 114 and the input terminals of the output stage 126 (i.e., the nodes N2A and N2B), are an implementation of the ping-pong switch SW_P2 shown in FIG. 1. Correspondingly, the nodes N1A and N1B are an implementation of the node N1 shown in FIG. 1.

Similarly, as shown in FIG. 4B, the pong stage 120 may also include four ping-pong switches SW_P3A, SW_P3B, SW_P4A and SW_P4B. The ping-pong switches SW_P3A and SW_P3B, which are coupled between the output terminals of the gain stage 124 and the input terminals of the output stage 116 (i.e., the nodes N1A and N1B), are an implementation of the ping-pong switch SW_P3 shown in FIG. 1. The ping-pong switches SW_P4A and SW_P4B, which are coupled between the output terminals of the gain stage 124 and the input terminals of the output stage 126 (i.e., the nodes N2A and N2B), are an implementation of the ping-pong switch SW_P4 shown in FIG. 1. Correspondingly, the nodes N2A and N2B are an implementation of the node N2 shown in FIG. 1.

Note that the present invention aims at providing a novel ping-pong amplifier which is capable of auto-zeroing to achieve offset cancellation with a lower circuit cost. Those skilled in the art may make modifications and alterations accordingly. For example, the circuit structures shown in FIGS. 4A and 4B are merely an exemplary implementation of the circuit stages of the ping-pong amplifier 10, and other types of amplifiers may be feasible. In addition, the switches (including the sampling switches, the ping-pong switches and/or the feedback switches) are coupled between the ping stage and the pong stage to realize the auto-zeroing and ping-pong operations, and the implementations of these switches are not limited to those illustrated in FIG. 1. As long as an amplifier has a ping-pong architecture with auto-zeroing functions which may be realized by using an appropriate switching control, the related implementations should belong to the scope of the present invention.

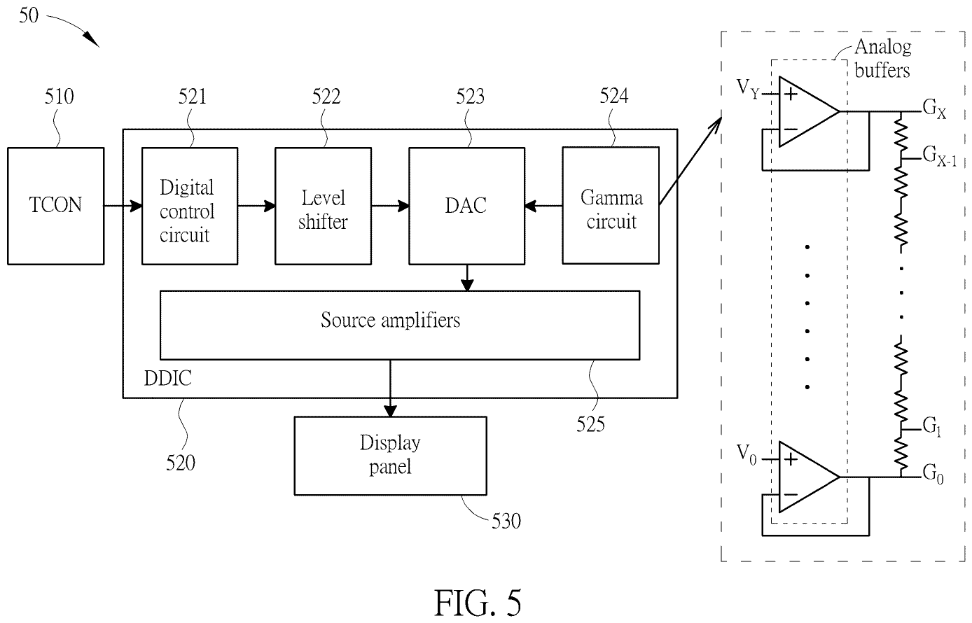

In one or some embodiments, the ping-pong amplifier of the present invention is applicable to realize an analog buffer of the gamma circuit included in a display driver circuit (such as a display driver integrated circuit (DDIC)). FIG. 5 is a schematic diagram of a display system 50 according to an embodiment of the present invention. The display system 50 includes a timing controller (TCON) 510, a display driver circuit (e.g., DDIC) 520 and a display panel 530. A detailed implementation of the display driver circuit 520 is shown in FIG. 5, which may include a digital control circuit 521, a level shifter 522, a digital-to-analog converter (DAC) 523, a gamma circuit 524 and a plurality of source amplifiers 525. The digital control circuit 521 is configured to receive and process the display data provided from the TCON 510. The level shifter 522 then shifts the display data to a level conforming to the display panel 530, and the display data are then converted into data voltages by the DAC 523. The data voltages are further sent to the display panel 530 through the corresponding source amplifiers 525.

The gamma circuit 524 is configured to provide gamma voltages G0-GX

for the DAC 523, allowing the DAC 523 to select suitable data voltages for the grayscales of the display data, where X may be any positive integer based on the granularity of the gamma curve. In the gamma circuit 524, the gamma voltages G₀-G_{X} are generated on a resistor string, which is driven by several analog buffers based on source voltages V₀-V_{Y}, where Y may be any positive integer smaller than or equal to X. In order to generate the accurate gamma voltages G₀-G_{X}, the offset of the analog buffers should be as small as possible. Therefore, a low-offset ping-pong amplifier such as the ping-pong amplifier 10 shown in FIG. 1 may be used to realize the analog buffers in the gamma circuit 524. The auto-zeroing function of the ping-pong amplifier may achieve the low offset, and the feature of continuous-time output of the ping-pong operations may provide sufficient driving capability to drive tremendous loads of a great number of source amplifiers 525 included in the display driver circuit 520.

To sum up, the present invention provides a novel ping-pong amplifier structure, which is capable of ping-pong operations to generate continuous-time output, and also capable of auto-zeroing operations to reduce the offset. In the ping-pong amplifier of the present invention, the ping-pong switches are coupled between the gain stage and the output stage, and the feedback circuit is connected to the front-end auto-zeroing circuit from the output terminal of the output stage. This connection manner may reduce the output ripples, and also reduce the number of V-to-I circuits and the number of capacitors required in the ping-pong amplifier, thereby reducing the circuit cost, while keeping a satisfactory offset cancellation effect.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A ping-pong amplifier comprising:
a ping stage, comprising:
a first input stage, comprising a first buffer circuit and a first auto-zeroing circuit;
a first gain stage, coupled to the first input stage;
a first output stage; and
a first storage capacitor, coupled to the first auto-zeroing circuit; and
a pong stage, coupled to the ping stage, comprising:
a second input stage, comprising a second buffer circuit and a second auto-zeroing circuit;
a second gain stage, coupled to the second input stage;
a second output stage; and
a second storage capacitor, coupled to the second auto-zeroing circuit;
wherein the first output stage is coupled to the first gain stage or the second gain stage, and the second output stage is coupled to the first gain stage or the second gain stage.

2. The ping-pong amplifier of claim 1, wherein the first output stage is coupled to the first gain stage and the second output stage is coupled to the second gain stage in a first phase, and the first output stage is coupled to the second gain stage and the second output stage is coupled to the first gain stage in a second phase.

3. The ping-pong amplifier of claim 1, wherein each of the ping stage and the pong stage includes only one storage capacitor.

4. The ping-pong amplifier of claim 1, further comprising:
a first ping-pong switch, coupled between the first gain stage and an input terminal of the first output stage;
a second ping-pong switch, coupled between the first gain stage and an input terminal of the second output stage;
a third ping-pong switch, coupled between the second gain stage and the input terminal of the first output stage; and
a fourth ping-pong switch, coupled between the second gain stage and the input terminal of the second output stage.

5. The ping-pong amplifier of claim 4, wherein the first ping-pong switch and the fourth ping-pong switch are turned on and the second ping-pong switch and the third ping-pong switch are turned off in a first phase, and the second ping-pong switch and the third ping-pong switch are turned on and the first ping-pong switch and the fourth ping-pong switch are turned off in a second phase.

6. The ping-pong amplifier of claim 1, further comprising:
a first feedback switch, coupled between the first auto-zeroing circuit and an output terminal of the first output stage;
a second feedback switch, coupled between the first buffer circuit and an output terminal of the second output stage;
a third feedback switch, coupled between the second auto-zeroing circuit and the output terminal of the first output stage; and
a fourth feedback switch, coupled between the second buffer circuit and the output terminal of the second output stage.

7. The ping-pong amplifier of claim 6, wherein the first feedback switch and the fourth feedback switch are turned on and the second feedback switch and the third feedback switch are turned off in a first phase, and the second feedback switch and the third feedback switch are turned on and the first feedback switch and the fourth feedback switch are turned off in a second phase.

8. The ping-pong amplifier of claim 1, further comprising:
a first sampling switch, coupled between a first input terminal of the first buffer circuit and a second input terminal of the first buffer circuit; and
a second sampling switch, coupled between a first input terminal of the second buffer circuit and a second input terminal of the second buffer circuit.

9. The ping-pong amplifier of claim 8, wherein the first sampling switch is turned on and the second sampling switch is turned off in a first phase, and the second sampling switch is turned on and the first sampling switch is turned off in a second phase.

10. The ping-pong amplifier of claim 1, wherein a first input terminal of the first buffer circuit and a first input terminal of the first auto-zeroing circuit are commonly coupled to an input terminal of the ping-pong amplifier, and a first input terminal of the second buffer circuit and a first input terminal of the second auto-zeroing circuit are commonly coupled to the input terminal of the ping-pong amplifier.

11. The ping-pong amplifier of claim 10, wherein the first storage capacitor is coupled to a second input terminal of the first auto-zeroing circuit, and the second storage capacitor is coupled to a second input terminal of the second auto-zeroing circuit.
